(19) United States
(12) Patent Application Publication
(10) Pub. No.: US 2011/0018096 A1
(43) Pub. Date: Jan. 27, 2011

(54) SEMICONDUCTOR DEVICE

(75) Inventors: Katsuya IZUMI, Kanagawa (JP); Kazutoshi Aogaki, Kanagawa (JP)

Correspondence Address: FOLEY AND LARDNER LLP;SUITE 500, 3000 K STREET NW, WASHINGTON, DC, 20007, US

(73) Assignee: NEC Electronics Corporation

(21) Appl. No.: 12/818,636

(22) Filed: Jun. 18, 2010

(30) Foreign Application Priority Data
Jul. 22, 2009 (JP) 2009-170857

(51) Int. Cl. H01L 27/108

(52) U.S. Cl. 257/532; 257/773; 257/E27.097

(57) ABSTRACT

A semiconductor device including: multiple layer wirings which are formed above a semiconductor substrate; multiple first electrode type contact plugs which have a granular shape in plane view, extend in a lower direction from the layer wirings to be connected to the layer wirings on an upper side, and serve as a first electrode; multiple second electrode type contact plugs which have a granular shape in plane view, extend in the lower direction from the layer wirings to be connected to the layer wirings on an upper side, and serve as a second electrode different from the first electrode; and a capacitative element section that fauns a capacity between adjacent ones of the first electrode type contact plugs and second electrode type contact plugs. The layer wirings serving as emergence portions of capacity electrodes of the first and second electrode type contact plugs are formed by different layer wirings.

### INCORPORATION BY REFERENCE

This application is based upon and claims the benefit of priority from Japanese patent application No. 2009-170857, filed on Jul. 22, 2009, the disclosure of which is incorporated herein in its entirety by reference.

### BACKGROUND

1. Field of the Invention

The present invention relates to a semiconductor device, and more particularly, to a semiconductor device including a capacitative element.

2. Description of Related Art

Along with the recent speeding-up of semiconductor devices, more decoupling capacitative elements are required to prevent noise. Meanwhile, the semiconductor devices have been miniaturized. Therefore, it becomes more difficult to secure an area in which the capacitative elements are inserted.

As a method to provide a semiconductor device that suppresses an increase in area thereof and includes a capacitative element having a high capacitance value, Japanese Unexamined Patent Application Publication No. 2005-136300 proposes a method of forming a parallel flat plate-shaped capacitative element simultaneously with a process for forming plug-vias to connect between layer wirings. FIG. 11 shows a schematic plane view of the semiconductor device disclosed in Japanese Unexamined Patent Application Publication No. 2005-136300. FIG. 12A shows a sectional view taken along the line XIIA-XIIA of FIG. 11. FIG. 12B shows a sectional view taken along the line XIIB-XIIB of FIG. 11.

As shown in FIGS. 12A and 12B, a lower interlayer dielectric 105 and an upper interlayer dielectric 106 are provided above a semiconductor substrate 151. The semiconductor device includes a logic section Ra having the logic transistor and a capacitative element section Rb having the capacitative element formed therein.

The logic section Ra includes a trench separation 152, which is formed in the surface part of the semiconductor substrate 151 and separates active regions, and a MIS (metal-insulator-semiconductor) transistor, which is formed in the active regions. The MIS transistor includes a gate insulating film 153, a gate electrode 154, side walls 155, and source/drain regions 156a, 156b. The lower interlayer dielectric 105 has plug-vias 157 that reach from the surface thereof to the source/drain regions 156a, 156b of the MIS transistor. First layer wirings 158, plug-vias 159, and second layer wirings 160 are provided on the plug-vias 157.

In the capacitative element section Rb, a first wiring 101 and a second wiring 102 are provided. The first wiring 101 includes a first lower wiring 101a formed by a common process with the first layer wirings 158 in the logic section Ra, a first upper wiring 101b formed by a common process with the second layer wirings 160 in the logic section Ra, and a first wall-like longitudinal wiring 101c formed by a common process with the plug-vias 159 in the logic section Ra. Similarly, the second wiring 102 includes a second lower wiring 102a formed by the common process with the first layer wirings 158, a second upper wiring 102b formed by the common process with the second layer wirings 160, and a second wall-like longitudinal wiring 102c formed by the common process with the plug-vias 159. The first lower wiring 101a and the first upper wiring 101b are connected to each other through the first wall-like longitudinal wiring 101c. Similarly, the second lower wiring 102a and the second upper wiring 102b are connected to each other through the second wall-like longitudinal wiring 102c.

The first wiring 101 includes the first lower wiring 101a, the first upper wiring 101b, and the first wall-like longitudinal wiring 101c. Similarly, the second wiring 102 includes the second lower wiring 102a, the second upper wiring 102b, and the second wall-like longitudinal wiring 102c. As shown in FIG. 11, the first upper wiring 101b and the second upper wiring 102b are opposed to each other in the surface direction of the substrate. The first upper wiring 101b has a plurality of pectinate portions and a connecting portion that connects one ends of the pectinate portions. Similarly, the second upper wiring 102b has a plurality of pectinate portions and a connecting portion that connects one ends of the pectinate portions. In plane view, the pectinate portions of the first upper wiring 101b and the pectinate portions of the second upper part wiring 102b are alternately formed through the upper interlayer dielectric 106.

Similarly, the first lower wiring 101a and the second lower wiring 102a are configured in the same manner as the first upper wiring 101b and the second upper wiring 102b. Furthermore, the first wall-like longitudinal wiring 101c and the second wall-like longitudinal wiring 102c are configured in the same manner as the first upper wiring 101b and the second upper wiring 102b.

As a method to provide a capacitor (capacitative element) that suppresses an increase in area thereof and has a high capacitance value, Japanese Unexamined Patent Application Publication No. 2002-124575 proposes a method that uses plug-vias. FIG. 13 shows a top view of layer wirings in a CMOS process of capacitative element disclosed in Japanese Unexamined Patent Application Publication No. 2002-124575. FIG. 14 shows a schematic side view of the capacitative element.

As shown in FIG. 13, metallization wirings 201 are separated by dielectric materials 202 and located in close proximity to one another. The metallization wirings 201 are connected to a bus 203 or a bus 204 depending on their polarities. As shown in FIG. 14, the plurality of metallization wirings 201 are disposed in the laminating direction. The metallization wirings 201 which are adjacent to each other in the laminating direction are connected by metal vias 205. The dielectric materials 202 are filled between the metal wirings 201. An interlevel dielectric material 206 is disposed between the metal vias 205. As shown in FIG. 14, a sidewall capacitance is formed by applying the metal vias 205.

### SUMMARY

According to the configuration disclosed in Japanese Unexamined Patent Application Publication No. 2005-136300, the plug-vias are formed in a parallel flat plate shape as shown in FIG. 12B. This makes it possible to form the capacitative element effectively. However, from the viewpoint of workability, it is extremely difficult to miniaturize the parallel flat plate as disclosed in Japanese Unexamined Patent Application Publication No. 2005-136300, along with the advancement in nanofabrication technology.

Meanwhile, in these days, the capacitative element which is high in design flexibility is desired depending on the specific usage and needs. However, in Japanese Unexamined Patent Application Publication No. 2002-124575, the design flexibility of the capacitative element is not high.

A first exemplary aspect of the present invention is a semiconductor device including: a plurality of layer wirings which are formed above a semiconductor substrate; a plurality of first electrode type contact plugs which are formed in a granular shape in plane view and extend in a lower direction from the layer wirings to be connected to the layer wirings on an upper side, the first electrode type contact plugs each serving as a first electrode; a plurality of second electrode type contact plugs which are formed in a granular shape in plane view and extend in the lower direction from the layer wirings to be connected to the layer wirings on the upper side, the second electrode type contact plugs each serving as a second electrode that is different from the first electrode; and a capacitative element section that forms a capacity between adjacent ones of the first electrode type contact plugs and the second electrode type contact plugs. The layer wirings serving as emergence portions of capacity electrodes of the first electrode type contact plugs and the layer wirings serving as emergence portions of capacity electrodes of the second electrode type contact plugs are formed by different layer wirings

As described above, in Japanese Unexamined Patent Application Publication No. 2005-136300, from the viewpoint of workability, it is extremely difficult to miniaturize the parallel flat plate along with the advancement in nanofabrication technology. Meanwhile, the present invention can cope with the miniaturization of a process, since the contact plugs are formed in a granular pattern in plane view. Moreover, along with the miniaturization of the process, a capacitance value can be obtained.

In Japanese Unexamined Patent Application Publication No. 2002-124575, the metallization wirings 201 having different polarities are alternately formed in the top layer thereof. Thus, the design flexibility of the top layer of the metallization wirings 201 is not high. According to the present invention, emergence portions of the capacity electrodes having different polarities are formed by different layers. Therefore, the design flexibility such as the shape or layout of the layer wirings can be enhanced.

The present invention has an advantageous effect of providing a semiconductor device which can cope with the advancement in nanofabrication technology, has a high design flexibility, and can form a capacitative element efficiently.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a schematic plane view of a semiconductor device according to a first exemplary embodiment of the present invention;

FIG. 2 is a sectional view taken along the line II-II of FIG. 1;

FIG. 3A is a schematic plane view of first layer wirings of a semiconductor device according to a first exemplary variation of the present invention;

FIG. 3B is a schematic plane view of second layer wirings of the semiconductor device according to the first exemplary variation;

FIG. 4A is a schematic plane view of first layer wirings of a semiconductor device according to a second exemplary variation of the present invention;

FIG. 4B is a schematic plane view of second layer wirings of the semiconductor device according to the second exemplary variation:

FIG. 5 is a schematic sectional view of a semiconductor device according to a second exemplary embodiment of the present invention;

FIG. 6 is a schematic sectional view of a semiconductor device according to a third exemplary embodiment of the present invention;

FIG. 7A is a schematic plane view of first layer wirings of a semiconductor device according to a fourth exemplary embodiment of the present invention;

FIG. 7B is a schematic plane view of second layer wirings of the semiconductor according to the fourth exemplary embodiment;

FIG. 8 is a sectional view taken along the line VIII-VIII of FIGS. 7A and 7B;

FIG. 9 is a circuit diagram of a delay circuit of a semiconductor device according to a fifth exemplary embodiment of the present invention;

FIG. 10A is a schematic plane view of a delay capacity of the semiconductor device according to the fifth exemplary embodiment;

FIG. 10B is a schematic plane view of a delay capacity of the semiconductor device according to the fifth exemplary embodiment;

FIG. 11 is a schematic plane view of a semiconductor device disclosed in Japanese Unexamined Patent Application Publication No. 2005-136300;

FIG. 12A is a sectional view taken along the line XIIA-XIIA of FIG. 11;

FIG. 12B is a sectional view taken along the line XIIB-XIIB of FIG. 11;

FIG. 13 shows a top view of layer wirings in a CMOS process of a capacitor disclosed in Japanese Unexamined Patent Application Publication No. 2002-124575; and

FIG. 14 shows a schematic side view of the capacitor disclosed in Japanese Unexamined Patent Application Publication No. 2002-124575.

### DETAILED DESCRIPTION OF THE EXEMPLARY EMBODIMENTS

Exemplary embodiments of the present invention will be described below. Note that other embodiments may also fall within the scope of the present invention, as long as they meet the purpose of the present invention. In addition, illustration and explanation of the component members except the characteristic part of the present invention will be omitted as appropriate.

### First Exemplary Embodiment

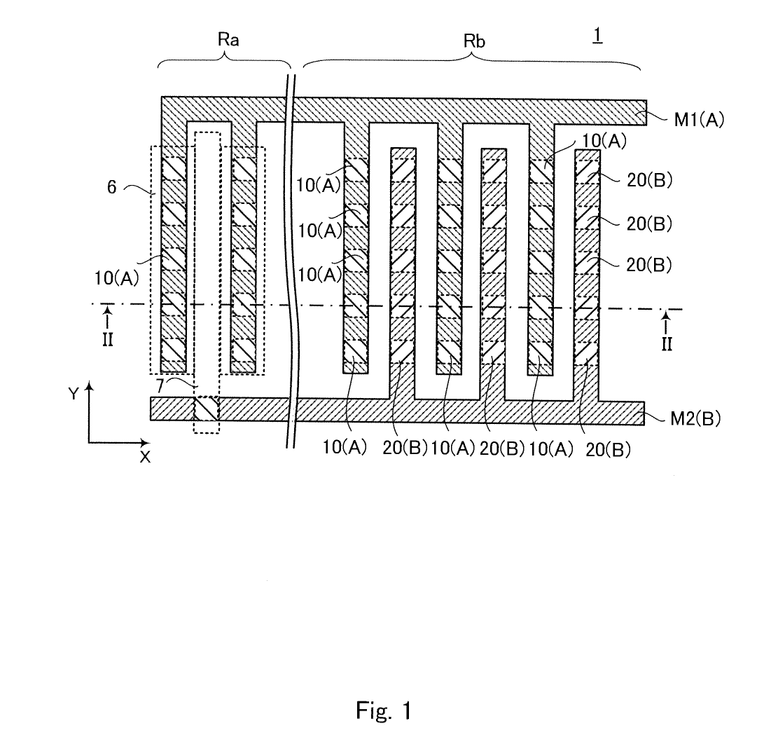

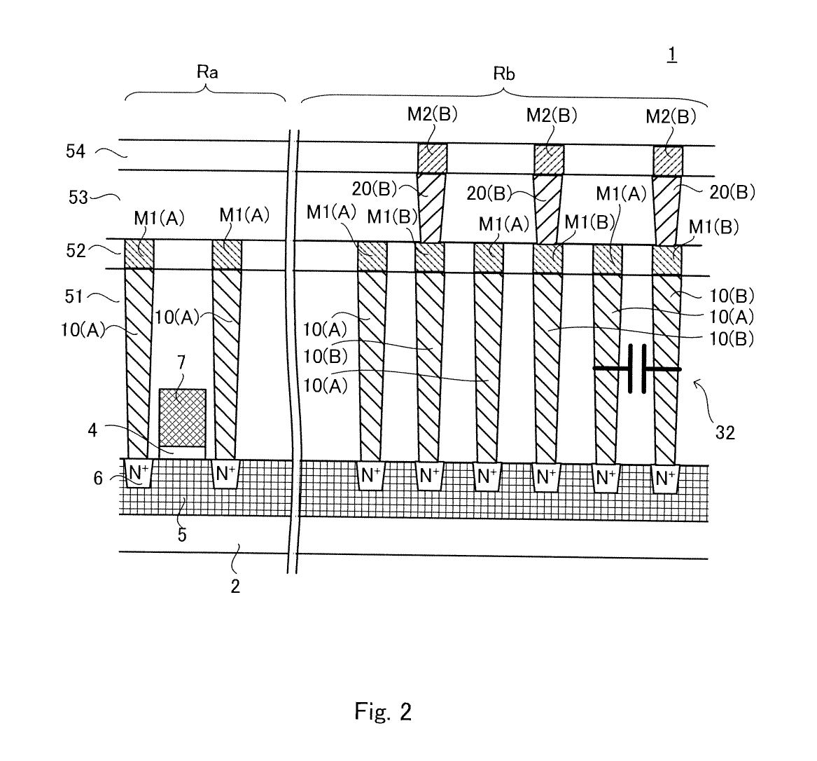

FIG. 1 is a schematic plane view of a semiconductor device according to a first exemplary embodiment of the present invention. FIG. 2 is a sectional view taken along the line II-II of FIG. 1. In FIG. 1, the positions of contact plugs are indicated by dotted lines for convenience of the explanation thereof.

A semiconductor device 1 includes a semiconductor substrate 2, active regions 6, a gate insulating film 4, a gate electrode layer 7, side walls (not shown), first layer wirings M1 and second layer wirings M2 functioning as layer wirings, contact plugs to be described later, a first interlayer dielectric 51, a second interlayer dielectric 52, a third interlayer dielectric 53, and a fourth interlayer dielectric 54.

Note that the term “layer wiring” herein described refers to an electrically conductive layer of the bottom layer in the wirings that are connected at an upper part of the contact plug, and to electrically conductive layers formed above the bottom layer in the wirings. Thus, the gate electrode layer 7 shown in FIG. 2 does not fall under “layer wiring” of the present specification. Meanwhile, the first layer wirings M1 and the second layer wirings M2 fall under “layer wiring”. The first layer wirings M1 are usually made of metallic materials. Further, the term “contact plug” herein described refers to conductive portions which extend in the lower direction from the above-mentioned “layer wirings” and which are formed in a granular shape in plane view, except conductive portions connected between the “layer wirings”.

Meanwhile, like Japanese Unexamined Patent Application Publication No. 2005-136300, the connecting plugs that are disposed between the “layer wirings” are referred to as “plug-via”, for convenience of the explanation. However, among the conductive portions connected between the “layer wirings”, conductive portions which are disposed so as to be integrally overlapped with the layer wirings and function as a capacity are exceptionally referred to as “contact plug”. Thus, among the plugs connecting between the first layer wirings, which are positioned in the bottom layer of the “layer wirings”, and the second layer wirings, which are formed above the first layer wirings through the insulating layer, plugs extending from the first layer wirings to the lower layer are exceptionally referred to as “contact plugs”.

The semiconductor device 1 according to the first exemplary embodiment includes contact plugs: first electrode type contact plugs 10(A) (hereinafter also referred to as “first electrode plug(s) 10(A)”) formed of a first electrode, second electrode type contact plugs 10(B) (hereinafter also referred to as “second electrode plug(s) 10(B)”) formed of a second electrode, and second electrode type contact plugs 20(B) (hereinafter also referred to as “second electrode plug(s) 20(B)”) formed of the second electrode. The second electrode plugs 10(B) and the second electrode plugs 20(B) are disposed through the first layer wirings M1 so as to be overlapped with each other in plane view, and are electrically connected to each other. Among the contact plugs, the adjacent first electrode plugs 10(A) and second electrode plugs 10(B) form a capacity. Emergence portions of the capacity electrodes of the first electrode type contact plugs and the second electrode type contact plugs are formed by different layer wirings. In the first exemplary embodiment, the emergence portions of the capacity electrodes of the first electrode type contact plugs are the first layer wirings M1. Similarly, the emergence portions of the capacity electrodes of the second electrode type contact plugs are the second layer wirings M2.

The semiconductor device 1 has a logic section Ra in which a MIS transistor is formed, and includes a capacitative element section Rb which is provided with a capacitative element 32. The semiconductor substrate 2 has a P-type well region 5 as shown in FIG. 2. The active regions 6, which are N+ active regions, are disposed within the P-type well 5.

The first layer wirings M1 have a first node M1(A) and second nodes M1(B). The first node M1(A) has a plurality of pectinate portions extending in the Y-direction in FIG. 1 and a connecting portion that connects one ends of the pectinate portions. The second nodes M1(B) are formed on the second electrode plugs 10(B). The size of the second nodes M1(B) is substantially the same as that of the second electrode plugs 10(B) or one size bigger than that of the second electrode plugs 10(B). The second layer wirings M2 have a second node M2(B). The second node M2(B) has a plurality of pectinate portions extending in the Y-direction in FIG. 1 and a connecting portion that connects one ends of the pectinate portions. The first node M1(A) and the second node M2(B) are formed in different layers. In plane view, the pectinate portions of the first node M1(A) and the pectinate portions of the second node M2(B) are formed alternately.

In the logic section Ra, the pectinate portions of the first node M1(A) are disposed in the positions corresponding to both ends in the cross direction of the gate electrode layer 7 that extends in the Y-direction. For example, the first node M1(A) is connected to a power supply potential VDD, and the second node M2(B) are connected to GND. Note that, electric potentials of the first node M1(A) and the second node M2(B) are not specifically limited in so far as they are 0 V or more.

The first electrode plugs 10(A) and the second electrode plugs 10(B) are disposed between the first layer wirings M1 and the active regions 6 that are formed in the semiconductor substrate 2. In other words, the first electrode plugs 10(A) and the second electrode plugs 10(B) are disposed within the first interlayer dielectric 51. The first electrode plugs 10(A) are connected to the first node M1(A), and the second electrode plugs 10(B) are connected to the second nodes M1(B).

The second electrode plugs 20(B) are disposed between the first layer wirings M1 and the second layer wirings M2. In other words, the second electrode plugs 20(B) are disposed within the third interlayer dielectric 53, and are disposed between the second nodes M1(B) and the second node M2(B).

The first electrode plugs 10(A), the second electrode plugs 10(B), and the second electrode plugs 20(B) include contact plugs formed in a granular shape in plane view as shown in FIGS. 1 and 2. The first electrode plugs 10 (A) and the second electrode plugs 10(B) and 20(B) are disposed alternately in the X-direction (a first direction) in FIG. 1. The adjacent first electrode plug 10(A) and second electrode plug 10(B) form a capacity. Note that the layout of each of the first electrode plugs 10(A), the second electrode plugs 10(B), and the second electrode plugs 20(B) is not specifically limited to the layout of FIG. 1 so far as the capacity is formed between the first electrode plugs 10(A) and the second electrode plugs 10(B).

The first electrode plugs 10 (A) and the second electrode plugs 10 (B) in both the logic section Ra and the capacitative element section Rb have the same contact plug size. The first electrode plugs 10 (A) and the second electrode plugs 10 (B) according to the first exemplary embodiment have the minimum size possible.

Note that, from the viewpoint of increasing a capacitance value, it is preferable to downsize the first electrode plugs 10(A) and the second electrode plugs 10(B). However, the size is not limited to the above-mentioned size, but can be changed as appropriate depending on objects and applications. Further, in the semiconductor device 1, the size of the contact plugs can be changed optionally. In addition, the electric potentials of the contact plugs disposed in the semiconductor device 1 are not limited to those of the first electrode plugs 10(A) and the second electrode plugs 10(B), and contact plugs of other electric potentials may be disposed.

Furthermore, the first electrode plugs 10(A) and the second electrode plugs 10(B) are not limited to those that are disposed between the first layer wirings M1 and the active regions 6 as described above by way of example. For example, like a third exemplary embodiment to be described later, the first electrode plugs 10(A) and the second electrode plugs 10(B) may be disposed in between an element isolation region and the layer wirings or between the insulating layer and the layer wirings.

A parasitic capacity between the wirings has been increasing with the recent advancement in miniaturization of semiconductor devices. Therefore, the parasitic capacity between the contact plugs formed by an advanced process becomes not negligible. In order to reduce the parasitic capacity between the wiring in the recent process, Low-K materials of low dielectric constants are usually used for the insulating layer where the first layer wirings M1 are disposed and for the insulating layer where the layer wiring which is an upper layer of the first layer wirings M1 is disposed. In contrast, the insulating layers that are provided under the first layer wirings M1 are commonly made of materials having a dielectric constant higher than that of Low-K materials, in view of strength or heat radiation.

Like Japanese Unexamined Patent Application Publication No. 2005-136300, when a parallel flat board-shaped capacitative element is fanned by the same process as that for plug-vias disposed between first layer wirings 158 and second layer wirings 160, Low-K materials are usually used as an insulating layer. However, the use of Low-K materials, which function as a capacitive insulating film, makes it difficult to obtain a large capacitance value. The same is true of the second or higher layer wirings.

Meanwhile, in the first exemplary embodiment, the capacitative element is formed between the contact plugs that connect the first layer wirings M1 and the active regions 6. Thus, in the semiconductor device of a typical multilayer wiring configuration, the materials having a high dielectric constant are used instead of Low-K materials. Therefore, the capacitative element has a larger capacitance value than that in the case of using Low-K materials. Further, the capacitative element having a small area in plane view and a high efficiency can be formed without any supplemental process. Besides, along with the advancement of miniaturization of the process, the distance between the contact plugs can be narrowed. Therefore, the capacitative element having a larger capacity can be obtained.

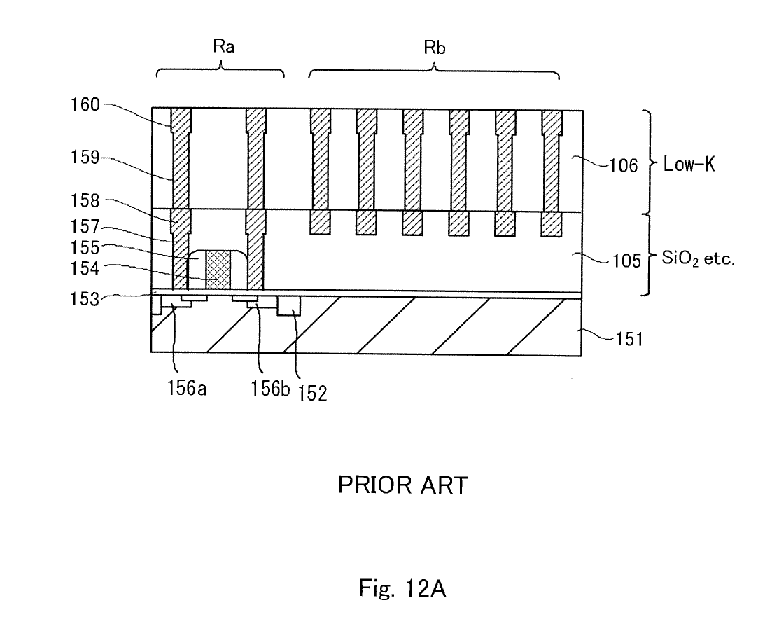

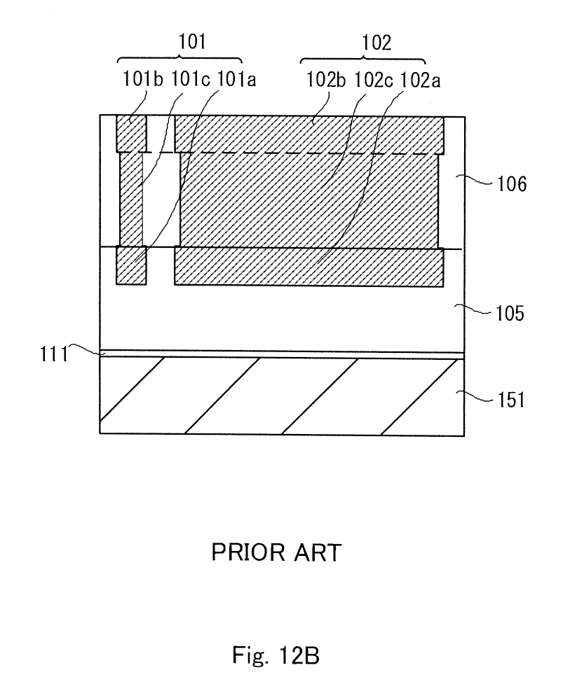

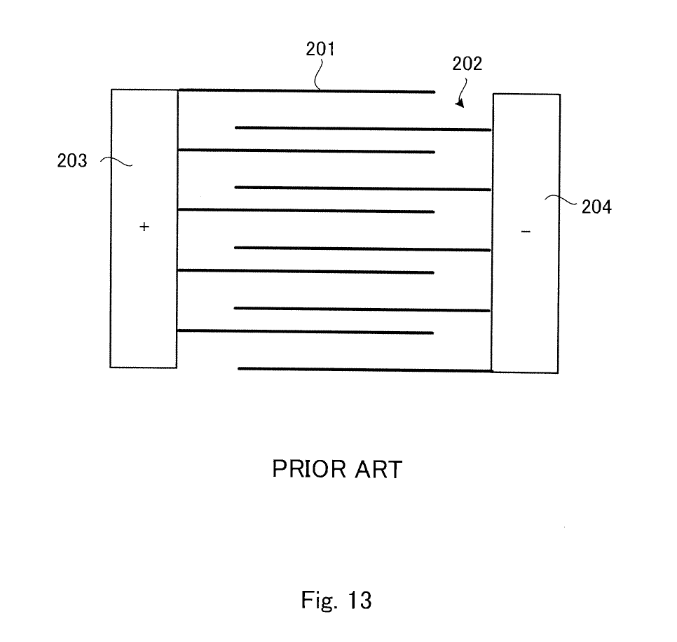

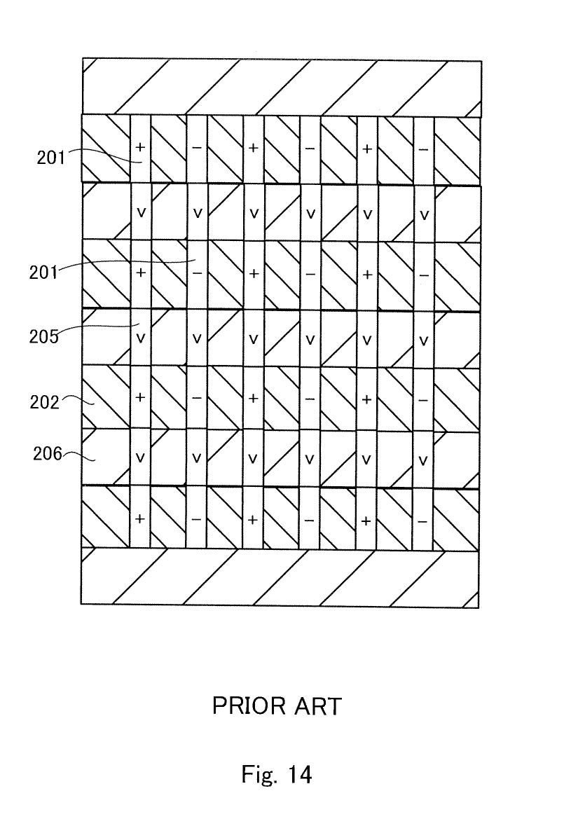

According to the first exemplary embodiment, the longitudinal plug-via as shown in FIG. 12B is not used. It is difficult to form the longitudinal contact plugs and the plug-vias by the recent process that has been miniaturized. Yet, it is difficult to form the longitudinal contact plug and plug-via with a minimum pitch at which the largest capacity can be ensured. In contrast, according to the first exemplary embodiment, a contact plug having a granular pattern in plane view constructs a capacitive element. Therefore, the formation of the contact plugs is possible for the process. The contact plugs can be formed at the minimum pitch at which the largest capacity ensured. Thus, in case a decoupling capacitative element is formed, a larger noise reduction effect can be expected. Further, in case a necessary capacity is fixed, the same noise reduction effect can be achieved with a smaller area.

In addition, the first exemplary embodiment has an advantageous effect that no additional process is required.

In Japanese Unexamined Patent Application Publication No. 2002-124575, as mentioned earlier, the metallization wirings 201 having different polarities are alternately formed in the top layer thereof. Thus, the design flexibility of the top layer of the metallization wirings 201 is not high. According to the first exemplary embodiment, since the emergence portions of the capacity electrodes of the layer wirings having different polarities are formed by different layer wirings, the design flexibility such as the shape or layout of the layer wiring can be enhanced. More specifically, the emergence portions of the capacity electrodes of the first electrode (A) are formed in the first layer wirings M1. Similarly, the emergence portions of the capacity electrodes of the second electrode (B) are formed in the second layer wirings M2. Therefore, these layers can enhance the wiring flexibility.

Note that the emergence portions of the capacity electrodes are not limited to the first layer wirings M1 and the second layer wirings M2. That is, it goes without saying that the emergence portions of the capacity electrodes may be formed in other layer wirings. Further, the contact plugs forming the capacity are not limited to the first electrode plugs 10(A) and the second electrode plugs 10(B). For example, in the upper layer overlapping the first electrode plugs 10(A), the first electrode plugs extending to the second layer wirings M2 may be disposed through the first layer wirings M1. In this case, a capacity may be formed by contact plugs disposed from the first interlayer dielectric 51 to the third interlayer dielectric 53. In that case, for example, emergence portions of the capacity electrode of a contact plug having one of the polarities may be provided in third layer wirings (not shown).

Further, the configuration to connect the second electrode plugs 20(B) to the second electrode plugs 10(B) through the first layer wirings M1 is described above by way of example. Alternatively, for example, the second electrode plugs 20(B) may be directly connected to the second electrode plugs 10(B) without interposing the first layer wirings M1. In this case, the second electrode plugs 20(B) may be formed to extend from the surface of the third interlayer dielectric 53 to the surface of the second electrode plugs 10(B). Furthermore, through-holes may be integrally formed from the surface of the third interlayer dielectric 53 to the surface of the active layers 6, and contact plugs may be disposed therein.

### (First Exemplary Variation)

Next, a description is given of an exemplary variation of a semiconductor device which is different from the above-mentioned exemplary embodiment. The basic configuration of a semiconductor device according to a first exemplary variation of the present invention is similar to that of the first exemplary embodiment, except for the following. That is, in the capacitative element section Rb according to the first exemplary embodiment, the first layer wirings M1 and the second layer wirings M2 are disposed such that the connecting portions which connect the pectinate portions are opposed to each other through the pectinate portions in plane view. Meanwhile, in the first exemplary variation, the connecting portions are disposed to overlap each other in plane view.

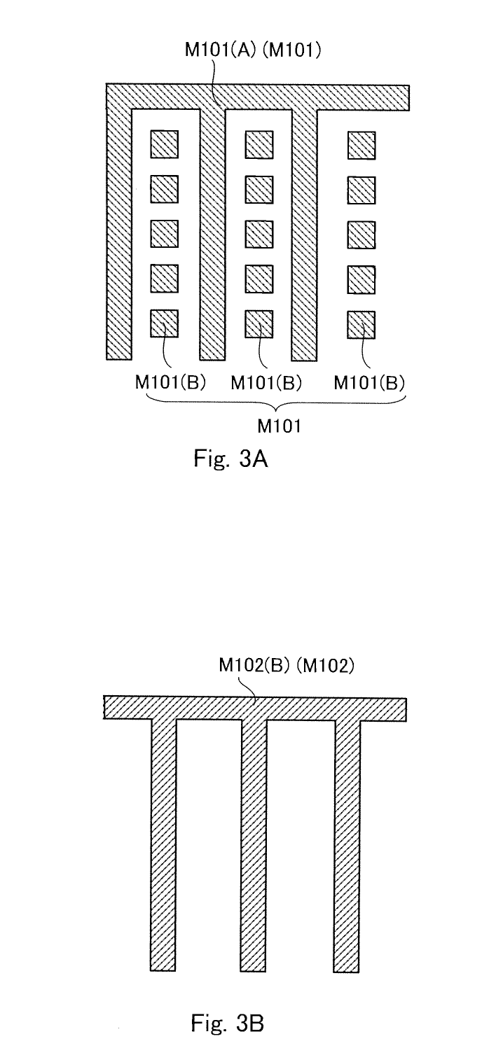

FIG. 3A shows a schematic plane view of first layer wirings M101 of the capacitative element section Rb in the semiconductor device according to the first exemplary variation. FIG. 3B shows a schematic plane view of second layer wirings M102 of the capacitative element section Rb in the semiconductor device according to the first exemplary variation. The configuration of the first layer wirings M101 is similar to that of the first exemplary embodiment. As shown in FIGS. 3A and 3B, the connecting portions of the pectinate portions of the first layer wirings M101 and the connecting portions of the pectinate portions of the second layer wirings M102 are located at substantially the same positions in plane view. Like the first exemplary embodiment, the emergence portions of the capacity electrodes of the layer wirings having different polarities are formed by different layer wirings. Specifically, the emergence portions of the capacity electrodes of the first electrode (A) are formed in the first layer wirings M101. Similarly, the emergence portions of the capacity electrodes of the second electrode (B) are formed in the second layer wirings M102.

According to the first exemplary variation, since the emergence portions of the capacity electrodes of the layer wirings having different polarities are formed by the different layer wirings, the design flexibility such as the shape or layout of the layer wiring can be enhanced. Additionally, since the connecting portions of the first layer wirings M101 and the connecting portions of the second layer wirings M102 are located at substantially the same positions in plane view, the occupation area in plane view of the capacitative element of the first exemplary variation can be reduced compared to the first exemplary embodiment. Furthermore, if a clearance between the first layer wirings M1 and the second layer wirings M2 is made small, a capacity can also be formed between these connecting portions. Specifically, a capacity may be formed between the connecting portion of a first node M101(A) and the connecting portion of a second node M102(B).

### (Second Exemplary Variation)

The basic configuration of a semiconductor device according to a second exemplary variation of the present invention is similar to that of the first exemplary embodiment, except for the following. That is, in the semiconductor device according to the first exemplary embodiment, the first layer wirings M1 and the second layer wirings M2 are formed in a ctenidium shape. In the semiconductor device according to the second exemplary variation, the second layer wirings M2 are form in a board shape.

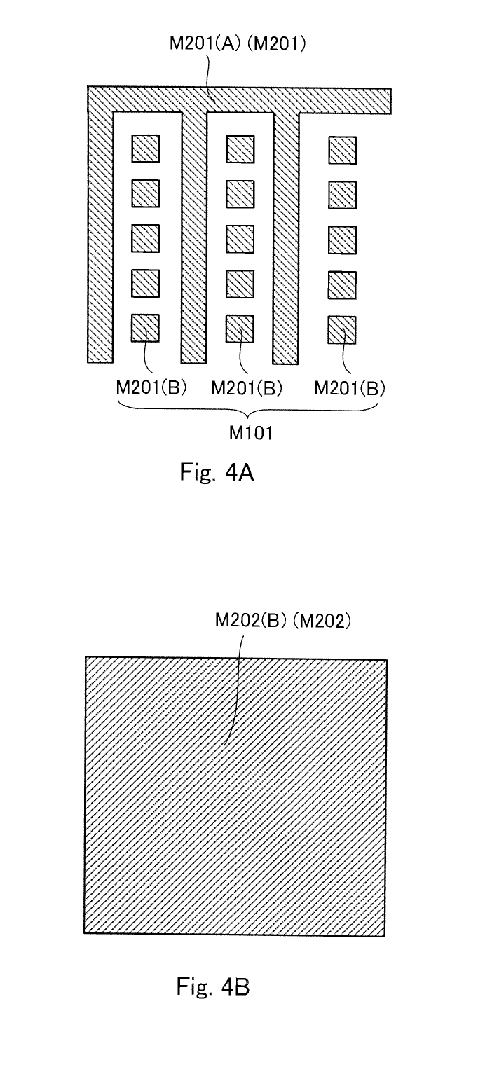

FIG. 4A shows a schematic plane view of first layer wirings M201 of the capacitative element section Rb in the semiconductor device according to the second exemplary variation. FIG. 4B shows a schematic plane view of second layer wirings M202 of the capacitative element section Rb in the semiconductor device according to the second exemplary variation. The configuration of the first layer wirings M201 is similar to that of the first exemplary embodiment. As shown in FIGS. 4A and 4B, a board portion of the second layer wirings M202 and the first layer wirings M201 are located to overlap each other in plane view. Like the first exemplary embodiment, the emergence portions of the capacity electrodes of the layer wirings having different polarities are formed by different layer wirings. Specifically, the emergence portions of the capacity electrodes of the first electrode (A) are faulted in the first layer wirings M201. Similarly, the emergence portions of the capacity electrodes of the second electrode (B) are faulted in the second layer wirings M202.

According to the second exemplary variation, since the emergence portions of the capacity electrodes of the layer wirings having different polarities are formed by the different layer wirings, the design flexibility such as the shape or layout of the layer wiring can be enhanced. Additionally, since the board portion of the second layer wirings M202 is formed within an overlapping area of the first layer wirings M201, the occupation area in plane view of the capacitative element of the second exemplary variation can be reduced compared to the first exemplary embodiment. Further, if a clearance between the first layer wirings M1 and the second layer wirings M2 is made small, a capacity can also be formed between these connecting portions. Specifically, a capacity may be formed between the overlapping portion of a first node M201(A) and the connecting portion of a second node M202(B).

### Second Exemplary Embodiment

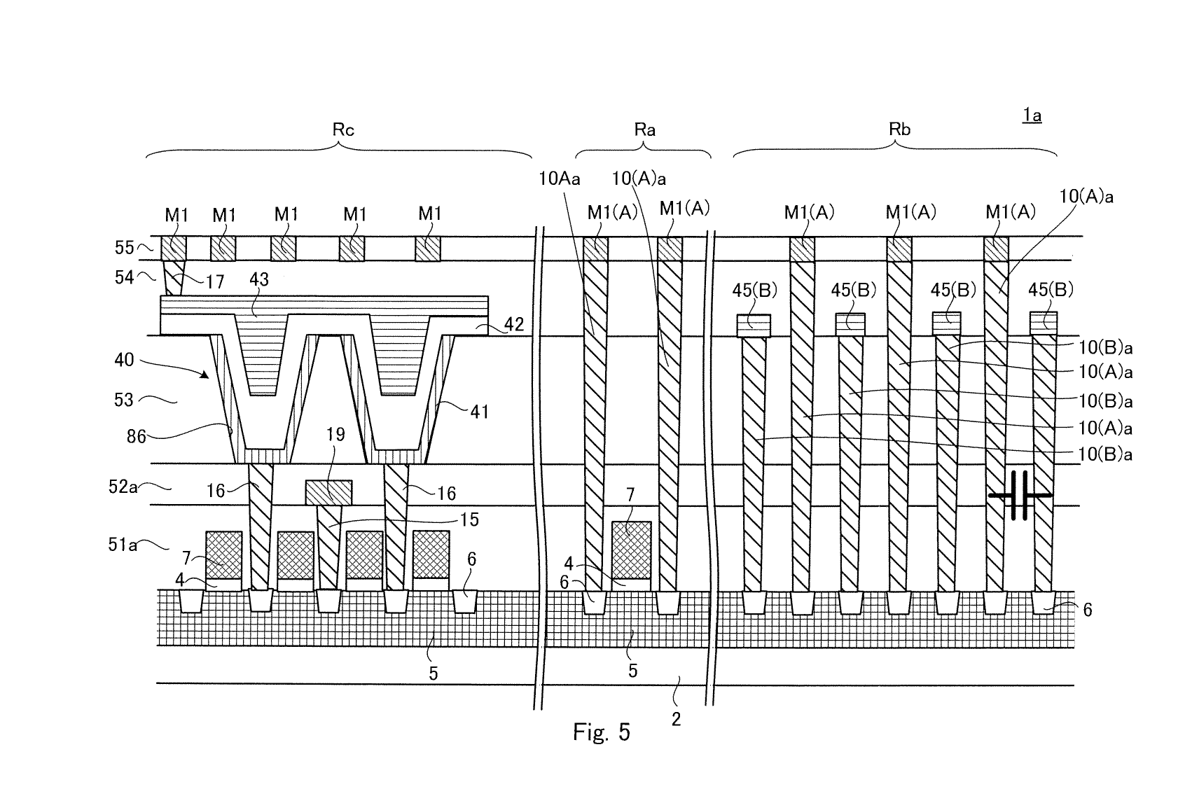

Next, a description is given of an example of a semiconductor device which is different from the above-mentioned exemplary embodiment. FIG. 5 shows a schematic sectional view of a semiconductor device 1a according to a second exemplary embodiment of the present invention. The semiconductor device 1a has the logic section Ra, the capacitative element section Rb, and a DRAM (Dynamic Random Access Memory) section Rc. As described earlier, the parasitic capacity between the wirings has been increasing along with the recent advancement in miniaturization of semiconductor devices. Therefore, the parasitic capacity between the contact plugs formed by an advanced process becomes not negligible. Particularly, in the case of a configuration in which contact plugs have a large height, such as a mixed DRAM of a stack type, the influence of the parasitic capacity has become more remarkable. The semiconductor device according to the second exemplary embodiment positively uses the parasitic capacity that occurs between adjacent contact plugs as a capacitative element.

The semiconductor device 1a includes the components shown in FIG. 2 of the first exemplary embodiment. As shown in FIG. 5, the semiconductor device 1a also includes bit line-contact plugs 15, MIM (Metal-Insulator-Metal)-contact plugs 16, first wiring-plug-vias 17, bit lines 19, a MIM capacity 40 functioning as a memory element, a first interlayer dielectric 51a, a second interlayer dielectric 52a, the third interlayer dielectric 53, the fourth interlayer dielectric 54, and a fifth interlayer dielectric 55. The MIM capacity 40 is formed in the DRAM section Rc, and includes a lower layer metal 41, a capacitive insulating film 42, and an upper layer metal 43. The semiconductor device 1a further includes upper layer metal wirings 45 formed by the same production process as that for the upper layer metal 43.

The first layer wirings M1 are formed on the fourth interlayer dielectric 54 as shown in FIG. 5. The bit lines 19 are disposed immediately above the first interlayer dielectric 51a of the DRAM section Rc. The bit lines 19 are electrically connected to the active regions 6 through the bit line-contact plugs 15. Further, in the DRAM section Rc, connection holes penetrating from the surface of the second interlayer dielectric 52a to the surface of the active regions 6 are formed, and the MIM-contact plugs 16 are buried in the connection holes.

An opening 86 penetrating to the surface of the second interlayer dielectric 52a is formed in the third interlayer dielectric 53 to form the MIM capacity 40. The opening 86 is formed to overlap the location where the MIM-contact plugs 16 are formed. The lower layer metal 41 of the MIM capacity 40 is formed to coat a bottom and side walls of the opening 86. Further, the capacitive insulating film 42 is laminated to coat the surface of the lower layer metal 41 and the surface of the third interlayer dielectric 53 of the around the opening 86. The upper layer metal 43 is laminated to coat the capacitive insulating film 42.

In the capacitative element section Rb, the upper layer metal wirings 45 overlap the second electrode plugs 10(B)a in plane view. In other words, the second electrode plugs 10(B)a are formed between the upper layer metal wirings 45 and the active regions 6. That is, the second electrode plugs 10(B)a are formed to penetrate from the third interlayer dielectric 53 to the first interlayer dielectric 51a.

The fourth interlayer dielectric 54 is formed to coat the MIM capacity 40 and the upper layer metal wirings 45. The first layer wirings M1 are formed on the fourth interlayer dielectric 54. In the DRAM section Rc, the first wiring-plug-vias 17 are disposed between the first layer wirings M1 and the MIM capacity 40. Meanwhile, in the capacitative element section Rb, the first electrode plugs 10(A)a are formed so that a capacity is formed between the first layer wirings M1 and the active regions 6. The first electrode plugs 10(A)a are formed to penetrate from the fourth interlayer dielectric 54 to the first interlayer dielectric 51a. The first electrode plugs 10(A)a and the second electrode plugs 10(B)a form a capacity in the area in which the first electrode plugs 10(A)a and the second electrode plugs 10(B)a are opposed. Note that the first electrode plugs 10 (A)a are not limited to the above-mentioned configuration. For example, the first electrode plugs 10(A)a may be formed such that the upper layer metal wirings 45 are disposed and contact plugs are then disposed on the upper layer metal wirings 45.

According to the second exemplary embodiment, contact plugs having the granular pattern in plane view are formed in the capacitive element section Rb. Therefore, the same effects as those of the first exemplary embodiment are provided. Further, according to the second exemplary embodiment, the capacitative element is applied to the semiconductor device of the mixed DRAM of the stack type. Therefore, the height of contact plugs forming the capacitative element can be increased. In comparison with a case to use plug-vias between the layer wirings as capacitative element as in Japanese Unexamined Patent Application Publication No. 2005-136300, the capacitative element according to the second exemplary embodiment has larger capacitance values.

Specifically, in the case of a normal logic process, the ratio of the height of the contact plug and the height of the plug-via is around 1:1. In contrast, in the case of a mixed DRAM of a stack-type cell, the ratio of the height of the contact plug and the height of the plug-via is approximately from 10:1 to 6:1. In the case of the mixed DRAM of the stack type, the contact plugs have a large height, so the lateral area of the contact plug can be increased depending on the height of the contact plug. Therefore, a larger capacity can be more effectively obtained.

Further, in semiconductor devices having the multilayer wiring configuration of the mixed DRAM like the second exemplary embodiment, it is usually common to apply a Low-K film in layers of the fifth interlayer dielectric 55 or higher interlayer dielectrics. According to the second exemplary embodiment, the capacitative element is typically forms a capacity in layers of the fourth interlayer dielectric 54 or lower interlayer dielectrics having a dielectric constant higher than that of the Low-K film. Therefore, larger capacitance values can be obtained compared to the case of applying the Low-K film.

In addition, according to the second exemplary embodiment, since the emergence portions of the capacity electrodes of the layer wirings having different polarities are formed by different layer wirings, the design flexibility such as the shape or layout of the layer wiring can be enhanced. More specifically, the emergence portions of the capacity electrodes of the first electrode (A) are formed in the first layer wirings M1. Meanwhile, the emergence portions of the capacity electrodes of the second electrode (B) are formed in the upper layer metal wirings 45. Therefore, these layers can enhance the wiring flexibility.

Note that, among “layer wirings” according to the second exemplary embodiment, the layer wiring which is located nearest to the semiconductor substrate 2 is the bit line 19. Thus, in the capacitative element section Rb, contact plugs to extend towards the lower layers of the layer wiring from the layer wirings of the same layer as the bit lines 19 may be used as a capacitative element. Further, the bit lines 19 are illustrated by way of example, and word lines may be disposed at the positions of the bit lines 19.

Further, the first electrode plugs 10(A)a and the second electrode plugs 10(B)a need not be connected to the semiconductor substrate 2, as long as they extend from the corresponding first layer wirings M1 in the lower direction. For example, the first electrode plugs 10(A)a and the second electrode plugs 10(B)a may be buried in the area from the fourth interlayer dielectric 54 to the second interlayer dielectric 52a.

### Third Exemplary Embodiment

Next, a description is given of an example of a semiconductor device which is different from the first exemplary embodiment. The basic configuration of a semiconductor device 1b according to a third exemplary embodiment of the present invention is similar to that of the first exemplary embodiment, except for the following. That is, in the first exemplary embodiment, the first electrode plugs 10(A) and the second electrode plugs 10(B) have a configuration in which layer wirings (the first layer wirings M1, the second layer wirings M2) and the active regions 6 are connected to each other. Meanwhile, in the third exemplary embodiment, the first electrode plugs and second electrode plugs are disposed between an element isolation region 3 and layer wirings (the first layer wirings M1, the second layer wirings M2).

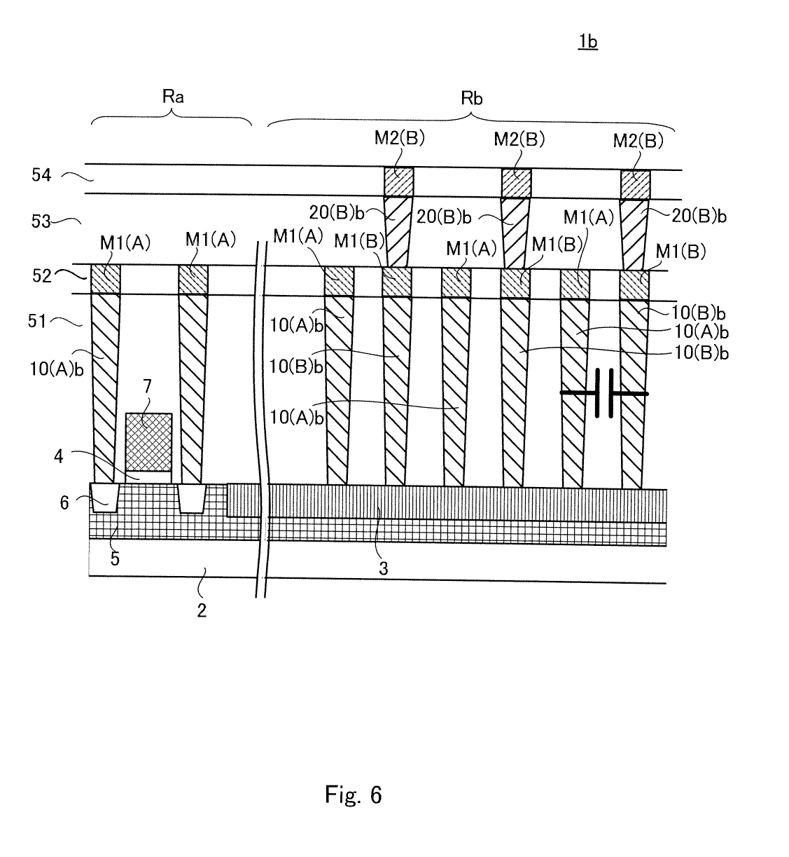

FIG. 6 shows a schematic sectional view of the semiconductor device according to the third exemplary embodiment of the present invention. As shown in FIG. 6, first electrode plugs 10(A)b and second electrode plugs 10(B)b are disposed within the first interlayer dielectric 51 such that the first electrode plugs 10(A)b and the second electrode plugs 10(B)b extend from immediately above the element isolation area 3, which is formed on the semiconductor substrate 2 in the capacitative element section Rb, to the first layer wirings M1. Further, in the capacitative element section Rb, second electrode plugs 20(B)b are disposed within the third interlayer dielectric 53 such that the second electrode plugs 20(B)b extend from immediately above the first layer wirings M1 to the second layer wirings M2. As shown in FIG. 6, the second electrode plugs 10(B)b and the second electrode plugs 20(B)b are located to overlap each other. Note that the first node M1(A) or/and the second nodes M1(B) may have an electric potential of 0 V or more, like in the first exemplary embodiment. Alternatively, both or either of the first node M1(A) and the second nodes M1(B) may have a negative potential.

According to the third exemplary embodiment, the same effects as those of the first exemplary embodiment can be obtained. According to the third exemplary embodiment, a leakage via the active regions can be theoretically prevented. Therefore, the capacitative element according to the third exemplary embodiment is particularly suitable for the filter capacity that involves a problem of leakage.

### Fourth Exemplary Embodiment

Next, a description is given of an example of a semiconductor device which is different from the first exemplary embodiment. The basic configuration of a semiconductor device according to a fourth exemplary embodiment of the present invention is similar to that of the first exemplary embodiment, except for the following. That is, in the first exemplary embodiment, the first electrode plugs 10(A) and the second electrode plugs 10(B) are alternately arranged in the X-direction (the first direction), and the plugs of the same electrode are arranged in the Y-direction (a second direction). Meanwhile, in the fourth exemplary embodiment, first electrode plugs and second electrode plugs are alternately arranged in both the X-direction and the Y-direction.

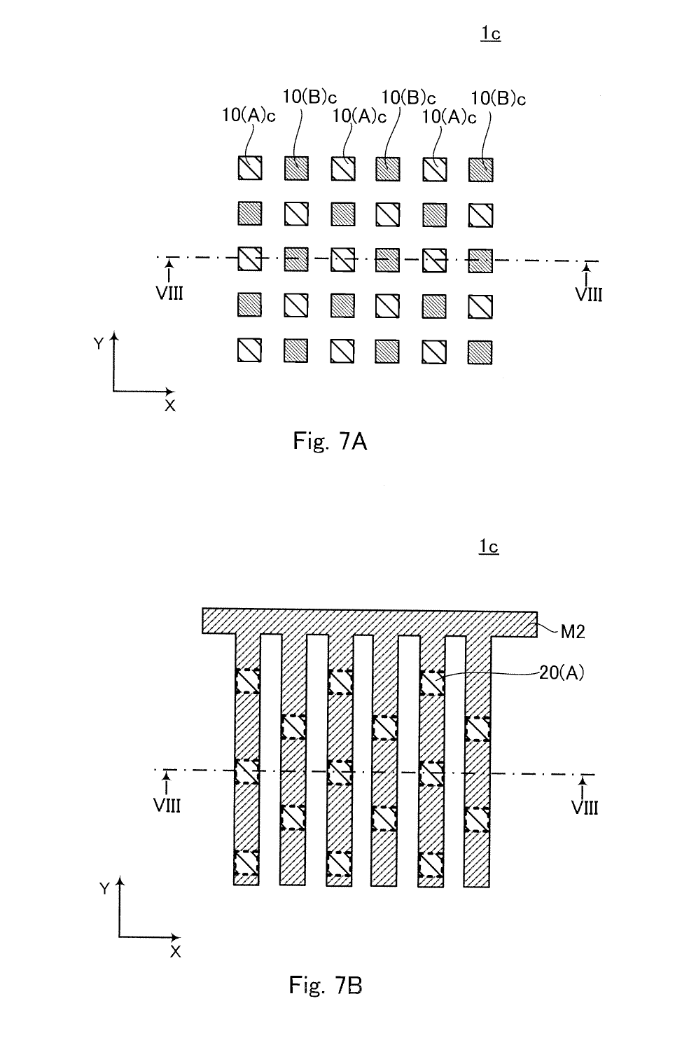

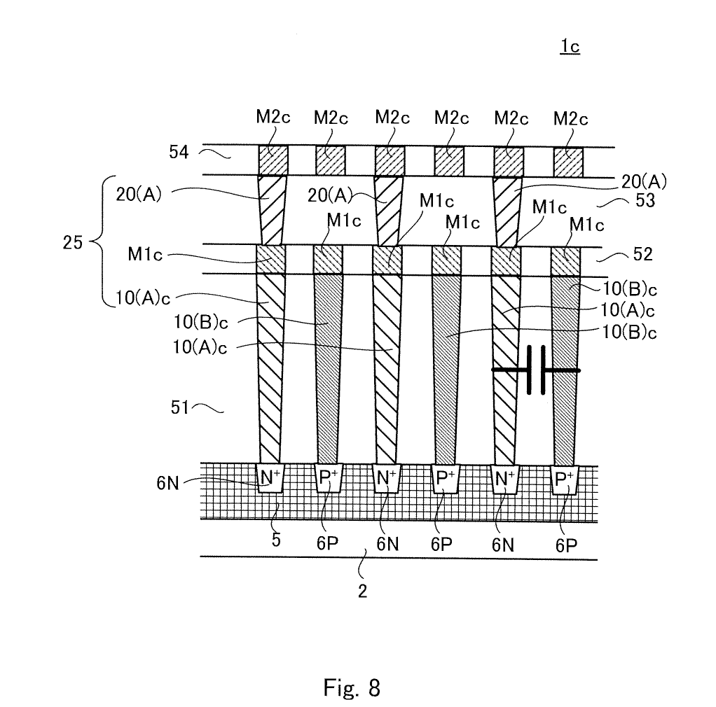

FIG. 7A shows a schematic plane view of first electrode plugs 10(A)c and second electrode plugs 10(B)c in the capacitative element section Rb of the semiconductor device according to the fourth exemplary embodiment of the present invention. FIG. 7B shows a schematic plane view of the second layer wirings M2 of the semiconductor according to the fourth exemplary embodiment. In FIG. 7B, the locations of first electrode type M2-contact plugs 20(A) (hereinafter referred to as “first electrode plug(s) 20(A)”) are indicated by dotted lines for convenience of the explanation. Further, FIG. 8 shows a sectional end view taken along the line VIII-VIII of FIGS. 7A and 7B. Note that, in the first exemplary embodiment, the first electrode plugs 10(A) and the second electrode plugs 10(B) are indicated by the same hatching. In contrast, in FIGS. 7 and 8, the first electrode plugs 10(A)c and the second electrode plugs 10(B)c are indicated by another hatching for convenience of the explanation.

In the capacitative element section Rb, the first electrode plugs 10(A)c and the second electrode plugs 10(B)c are arranged in a checkered pattern in plane view (see FIG. 7A). In other words, the first electrode plugs 10(A)c and the second electrode plugs 10(B)c are alternately arranged in both the X-direction (the first direction) and the Y-direction (the second direction). Note that the first direction and the second direction need not be orthogonal to each other.

In the capacitative element section Rb, the first layer wirings M1c have substantially the same shape as that of the first electrode plugs 10(A)c and the second electrode plugs 10(B)c, and overlap the first electrode plugs 10(A)c and the second electrode plugs 10(B)c. In other words, the first layer wirings M1c of the capacitative element section Rb are formed in a granular shape as with the first electrode plugs 10(A)c and the second electrode plugs 10(B)c (see FIG. 8).

The second layer wirings M2c have pectinate portions that extend in the Y-direction as shown in FIG. 7B, and a connecting portion that extends in the X-direction on the upper side of FIG. 7B and connects the above-mentioned pectinate portions. For example, the second layer wirings M2c are connected to the power supply potential VDD.

The first layer wirings M1c, which are formed in a granular shape, and the second layer wirings M2c are connected by the first electrode plugs 20(A). The First electrode plugs 20(A) are located to be connected to the first electrode plugs 10(A)c through the first layer wirings M1c. In other words, the first electrode plugs 20(A) are disposed through the first layer wirings M1c above the upper layer in which the first electrode plugs 10(A)c are disposed.

Meanwhile, the first layer wirings M1c are laminated on the upper layer in which the second electrode plugs 10(B) are disposed but contact plugs are not disposed.

The first electrode plugs 10(A)c, the first layer wirings M1c, and the first electrode plugs 20(A), which are formed in separate processes, function as contact plugs 25 composed of the first electrode to form a capacitative element (see FIG. 8). Further, the second electrode plugs 10(B)c and the first layer wirings M1c function as contact plugs composed of the second electrode.

The first electrode plugs 10(A)c and the second electrode plugs 10(B)c are connected to the active regions 6. The first electrode plugs 10(A)c are connected to active regions 6N functioning as N+active regions, and the second electrode plugs 10(B)c are connected to active regions 6P functioning as P+active regions. A P-well 5 functions as GND.

That is, as for the GND node, an electric potential is supplied to the second electrode plugs 10(B)c through the P-well 5 and the active regions 6P functioning as P+ active regions. Meanwhile, as for the VDD node, an electric potential is supplied to the first electrode plugs 10(A)c from the second layer wirings M2. The VDD node is connected to the active regions 6N functioning as N+ active regions. Assuming that the voltage of the VDD node is higher than that of the GND node, the VDD node can be isolated without leakage on the P-well 5 side. Thus, the capacitative element in accordance with the fourth exemplary embodiment can also be used as a node of the filter capacity.

According to the fourth exemplary embodiment, the same effects as those of the first exemplary embodiment can be obtained. Note that the P-well 5 may be replaced by an N-well, and the P+ active regions and the N+ active regions may be replaced with each other. In this case, the capacitative element may be achieved by using the second layer wirings M2 as negative nodes, and the N-well as positive nodes. Furthermore, the N+ active regions 6N may be used for element isolation.

### Fifth Exemplary Embodiment

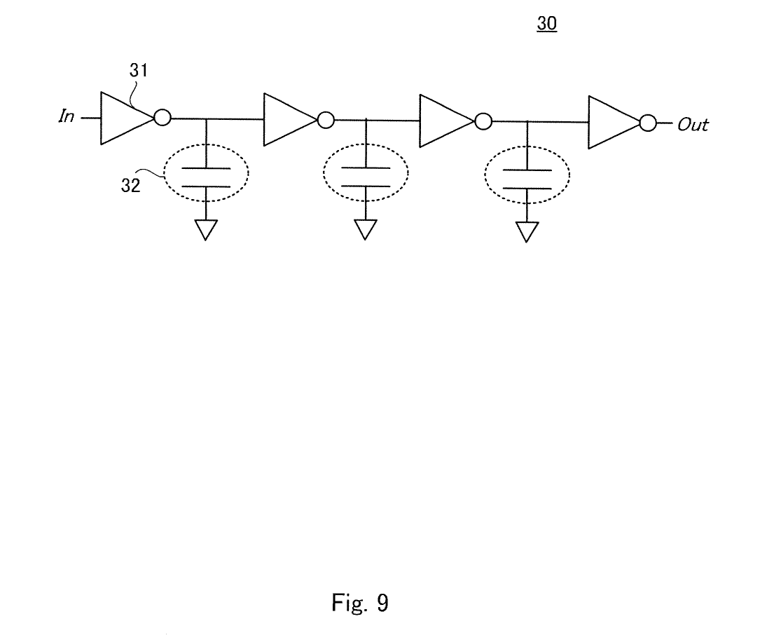

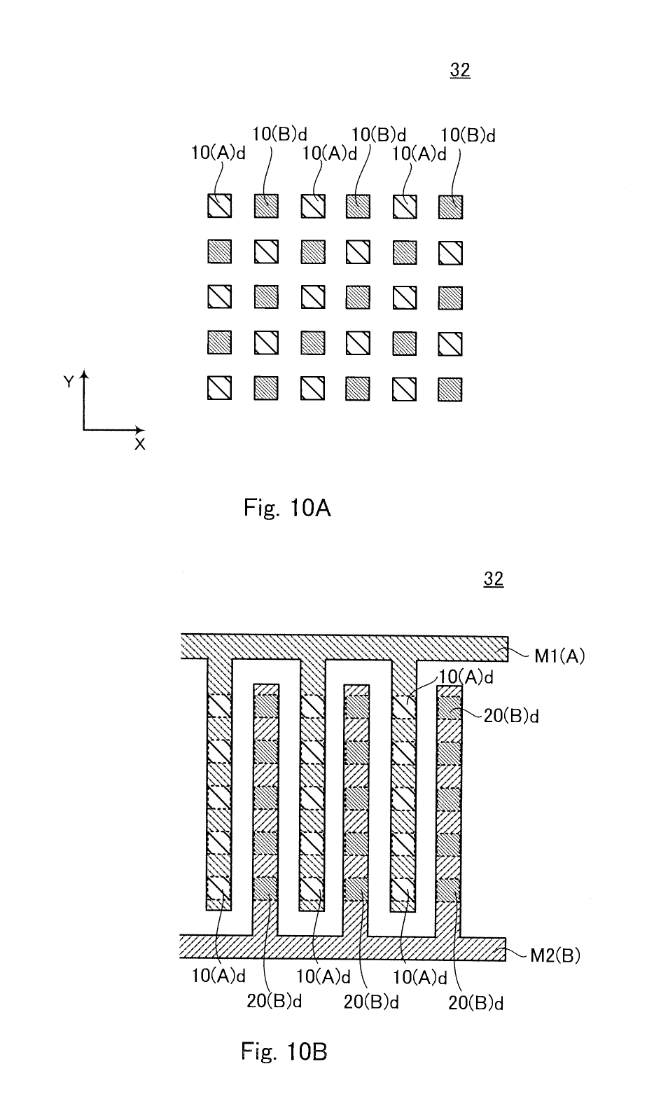

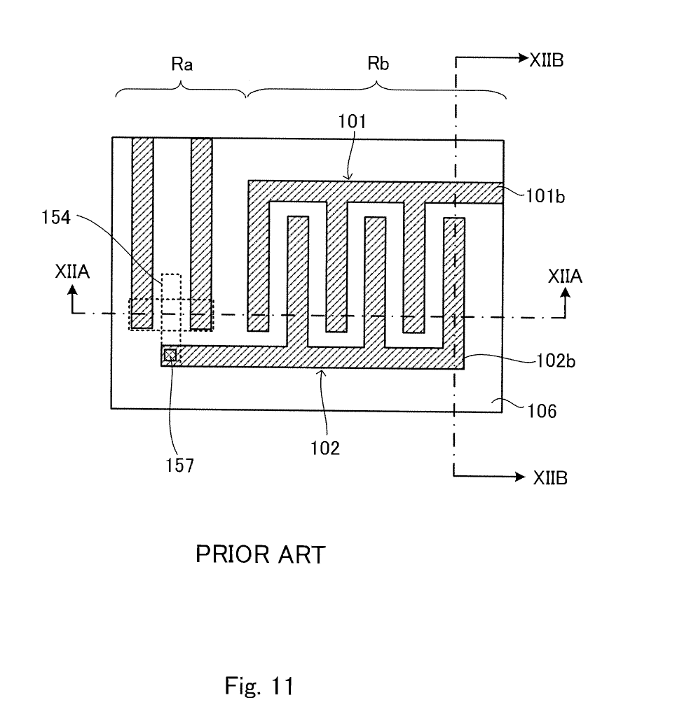

Next, a description is given of an example where the capacitative element according to an exemplary embodiment of the present invention is applied to a delay capacity in a delay circuit. FIG. 9 shows a circuit diagram of the delay circuit of a semiconductor device according to a fifth exemplary embodiment of the present invention. Further, FIG. 10A shows a schematic plane view illustrating a layout of first electrode plugs 10(A)d and second electrode plugs 10(B)d in the capacitative element of the delay circuit. FIG. 10B shows a schematic plane view of the first layer wirings M1 and the second layer wirings M2. In FIG. 10B, locations of the first electrode plugs 10(A)d and second electrode plugs 20(B)d are indicated by dotted lines for convenience of the explanation.

As shown in FIG. 9, a delay circuit 30 includes inverters 31 and delay capacities (capacitors) 32. As shown in FIG. 10A, the delay capacities 32 are formed by the first electrode plugs 10(A)d and the second electrode plugs 10(B)d. The first electrode plugs 10(A)d are connected to the first nodes M1(A) functioning as the first layer wirings. Meanwhile, the second electrode plugs 10(B)d are connected to the second node M2(B) through the second nodes M1(B) (not shown) and the second electrode plugs 20(B)d (see FIGS. 10A and 10B). The first node M1 (A) is connected to the inverters 31, and the second node M2 (B) is connected to GND.

The first electrode plugs 10(A)d and the second electrode plugs 10(B)d are alternately arranged in the X-direction (the first direction) in FIG. 10A. A capacity is formed between the adjacent first electrode plugs 10(A)d and second electrode plugs 10(B)d. Note that the layout of the first electrode plugs 10(A)d and the second electrode plugs 10(B)d is not limited to the layout of FIGS. 10A and 10B, as long as a capacity is formed between the first electrode plugs 10(A)d and the second electrode plugs 10(B)d.

Usually, a gate capacity is used as a delay capacity. However, when the gate capacity is applied, a large area is required for a plate capacity, and capacitance values cannot be finely adjusted by the layout change. Meanwhile, if a capacitative element consisting of a plurality of granular contact plugs is applied as a delay capacity, as shown in FIGS. 10A and 10B, a design including addition or deletion of contact plugs can be performed for each contact plug. Thus, capacitance values can be finely adjusted. Along with the nanofabrication technology by an advanced process, a finer adjustment becomes possible. Thus, a finer adjustment of delay values becomes possible.

According to the fifth exemplary embodiment, the same effects as those of the first exemplary embodiment can be obtained. Because a finer adjustment of capacitance values is possible, the capacitative element according to the fifth exemplary embodiment can be preferably applied to a delay circuit and the like.

While the invention has been described in terms of several exemplary embodiments, those skilled in the art will recognize that the invention can be practiced with various modifications within the spirit and scope of the appended claims and the invention is not limited to the examples described above.

The first to fifth exemplary embodiments can be combined as desirable by one of ordinary skill in the art.

Further, the scope of the claims is not limited by the exemplary embodiments described above.

Furthermore, it is noted that, applicant's intent is to encompass equivalents of all claim elements, even if amended later during prosecution.

What is claimed is:

1. A semiconductor device comprising:
a plurality of layer wirings which are formed above a semiconductor substrate;
a plurality of first electrode type contact plugs which are formed in a granular shape in plane view and extend in a lower direction from the layer wirings to be connected to the layer wirings on an upper side, the first electrode type contact plugs each serving as a first electrode;
a plurality of second electrode type contact plugs which are formed in a granular shape in plane view and extend in the lower direction from the layer wirings to be connected to the layer wirings on the upper side, the second electrode type contact plugs each serving as a second electrode that is different from the first electrode; and
a capacitative element section that forms a capacity between adjacent ones of the first electrode type contact plugs and the second electrode type contact plugs,
wherein the layer wirings serving as emergence portions of capacity electrodes of the first electrode type contact plugs and the layer wirings serving as emergence portions of capacity electrodes of the second electrode type contact plugs are formed by different layer wirings.

2. The semiconductor device according to claim 1, wherein the first electrode type contact plugs and the second electrode type contact plugs disposed in the capacitative element section are connected to one of an active region and an element isolation region formed in the semiconductor substrate.

3. The semiconductor device according to claim 1, wherein the first electrode type contact plugs and the second electrode type contact plugs disposed in the capacitative element section are alternately arranged in a first direction and are alternately arranged in a second direction that is different from the first direction.

4. The semiconductor device according to claim 2, wherein the first electrode type contact plugs and the second electrode type contact plugs disposed in the capacitative element section are alternately arranged in a first direction and are alternately arranged in a second direction that is different from the first direction.

5. The semiconductor device according to claim 1, wherein a DRAM section is formed in a region different from the capacitative element section, and an upper side of contact plugs disposed in the capacitative element section is connected to an upper metal layer of a storage element formed in the DRAM section, or to layer wirings disposed in an upper layer of the upper metal layer.

6. The semiconductor device according to claim 2, wherein a DRAM section is formed in a region different from the capacitative element section, and an upper side of contact plugs disposed in the capacitative element section is connected to an upper metal layer of a storage element formed in the DRAM section, or to layer wirings disposed in an upper layer of the upper metal layer.

7. The semiconductor device according to claim 3, wherein a DRAM section is formed in a region different from the capacitative element section, and an upper side of contact plugs disposed in the capacitative element section is connected to an upper metal layer of a storage element formed in the DRAM section, or to layer wirings disposed in an upper layer of the upper metal layer.

8. The semiconductor device according to claim 1, wherein the capacitative element section is used as a delay capacity of a delay circuit.

9. The semiconductor device according to claim 2, wherein the capacitative element section is used as a delay capacity of a delay circuit.

10. The semiconductor device according to claim 3, wherein the capacitative element section is used as a delay capacity of a delay circuit.
